(19) United States
(12) Patent Application Publication
(10) Pub. No.: US 2010/0065106 A1
(43) Pub. Date: Mar. 18, 2010

(54) FLOATING WATER INTEGRATED PHOTOVOLTAIC MODULE

(76) Inventor: Barak Yekutiely, Kochav Yair (IL)

Correspondence Address: David Klein;DEKEL PATENT LTD., Beit HaRof' im, 18 Menuha VeNahala Street, Room 27, Rehovot, IL

(21) Appl. No.: 12/211,831

(22) Filed: Sep. 17, 2008

(51) Int. Cl. H01L 31/042; E04F 13/08

(52) U.S. Cl. 136/251; 156/299

(57) ABSTRACT

A WIPV (Water Integrated Photovoltaic) module including a photovoltaic (PV) device bonded to a geomembrane with an adhesive interface, the adhesive interface being formed with a buoyancy chamber that is at least partially filled with a material, wherein a volume of the buoyancy chamber and properties of the material are selected such that the PV device does not completely sink below an upper surface of a body of water when the WIPV module is placed on the body of water.

### FIELD OF THE INVENTION

The present invention relates generally to photovoltaic (PV) cells or modules (also referred to as solar cells or modules), and particularly to PV modules bonded to a geomembrane as a source of solar generated electricity, wherein the PV modules float on a body of water.

### BACKGROUND OF THE INVENTION

Geomembranes are liners or membranes that may be used to cover bodies of water, e.g., ponds, reservoirs, pools and the like. Geomembranes provide low cost, long-term lining and covering solutions and are available from various manufacturers, such as GSI (http://www.geo-synthetics.com/index.html). One brand from GSI is the Pondgard® EPDM Liner, which is a highly flexible liner with superior strength characteristics. The liner is safe for all fish and plants and is very UV stable. Another example is the blended Medium Density Polyethylene (MDPE) geomembrane which is low cost, long-lasting and has excellent elongation characteristics, which make it readily moldable around unusual shapes. The liner has a high carbon black content which provides extreme resistance to UV degradation.

PCT published application WO 2008/012791 to the present inventors/assignees describes the concept of WIPV (Water Integrated Photovoltaic) Technology/Systems. WIPV technology/systems/installations have the following advantages:

1. Protect precious clean water sources from evaporation by using a WIPV floating solar cover made of prefabricated or field-installed geomembrane and solar cells and/or modular interconnected solar cells (flexible or other and modularly connected using interconnecting elements) that float or are buoyant and have direct contact with the water body.

2. Large scale efficient energy creation system/power plant using any type of water surface area as opposed to expensive land area.

3. Large scale efficient water creation, water delivery, water rehabilitation, water treatment system without requiring any onsite energy.

4. Substantial increase of solar energy compared to non-WIPV solar array installations due to constant water cooling of solar cells from water bodies.

5. Very environmentally friendly green technology (blends in perfectly with the environment) unlike solar arrays and wind turbines that are visible and interfere with the environment

Other advantages of WIPV type installations/systems:

Water bodies not only cool the solar cells, but also can be used for cleaning the solar cells from dust/dirt. The WIPV cells can be used as a natural solar concentrator because they can be immersed or be buoyant at a water level for maximum solar radiation. Alternatively for a floating WIPV installation, water can be sprayed on the panel creating millions of magnifying glasses that increase the solar radiation and concentrate the suns rays on the solar material.

WIPV can be adapted to function in other industries such as gas creation, land fills, etc. The WIPV concept can be used in a great variety of applications, such as but not limited to, WIPV Power Plant, WIPV Water Plant, WIPV water channel, WIPV water pipe, WIPV reservoir, WIPV gas collection/power system, WIPV desalination plant, WIPV irrigation system, WIPV pumping system, WIPV water delivery system, WIPV open water desalination plant, WIPV water treatment plant, WIPV maritime energy system, WIPV maritime mobile water desalination system, WIPV maritime national border defense system, WIPV bridge, or WIPV water transportation system.

PCT published application WO 2007/141773 to the present inventors/assignees describes a solar cell geomembrane assembly including a solar cell integrated with a geomembrane. The solar cell may be disposed on or attached to the geomembrane. The geomembrane includes a flexible floating cover material that floats on a water surface or alternatively partially submerged below a water surface (in which case, water above the geomembrane functions as a magnifying glass to amplify suns rays that impinge upon the solar cell).

### SUMMARY OF THE INVENTION

The present invention seeks to improve upon the PV cell assembly of PCT published application WO 2007/141773. As described more in detail hereinbelow, the present invention seeks to bond PV modules to a geomembrane with a foam adhesive so that the PV modules float on a body of water. The solar membrane thus created serves a dual function: it acts as a conventional geomembrane (e.g., for controlling water evaporation and other uses), and it may be used to generate energy, such as for water related applications.

There is provided in accordance with an embodiment of the present invention a WIPV (Water Integrated Photovoltaic) module including a photovoltaic (PV) device bonded to a geomembrane with an adhesive interface, the adhesive interface being formed with a buoyancy chamber that is at least partially filled with a material, wherein a volume of the buoyancy chamber and properties of the material are selected such that the PV device does not completely sink below an upper surface of a body of water when the WIPV module is placed on the body of water.

The volume of the buoyancy chamber and the properties of the material may be selected such that the PV device is completely above, or partially submerged below, the top surface of the body of water when the WIPV module is placed on the body of water.

There is also provided in accordance with an embodiment of the present invention an interface for a WIPV module including an adhesive interface formed with a buoyancy chamber that is at least partially filled with a material, the adhesive interface being sufficiently adhesive to bond a PV device to a geomembrane, wherein a volume of the buoyancy chamber and properties of the material are selected such that the PV device does not completely sink below an upper surface of a body of water when the PV device together with the adhesive interface and geomembrane is placed on the body of water.

There is also provided in accordance with an embodiment of the present invention a method for constructing a WIPV module including bonding a photovoltaic (PV) device to a geomembrane with an adhesive interface, the adhesive interface being formed with a buoyancy chamber that is at least partially filled with a material, and selecting a volume of the buoyancy chamber and properties of the material such that the PV device does not completely sink below an upper surface of a body of water when the WIPV module is placed on the body of water.

### BRIEF DESCRIPTION OF THE DRAWINGS

The present invention will be understood and appreciated more fully from the following detailed description taken in conjunction with the drawings in which:

FIG. 1 is a simplified illustration of a WIPV (Water Integrated Photovoltaic) module, constructed and operative in accordance with an embodiment of the present invention; and

FIG. 2 is a simplified illustration of adjacent PV devices mounted on a geomembrane, with troughs or gaps created between adjacent PV devices, in accordance with an embodiment of the present invention.

### DETAILED DESCRIPTION OF EMBODIMENTS

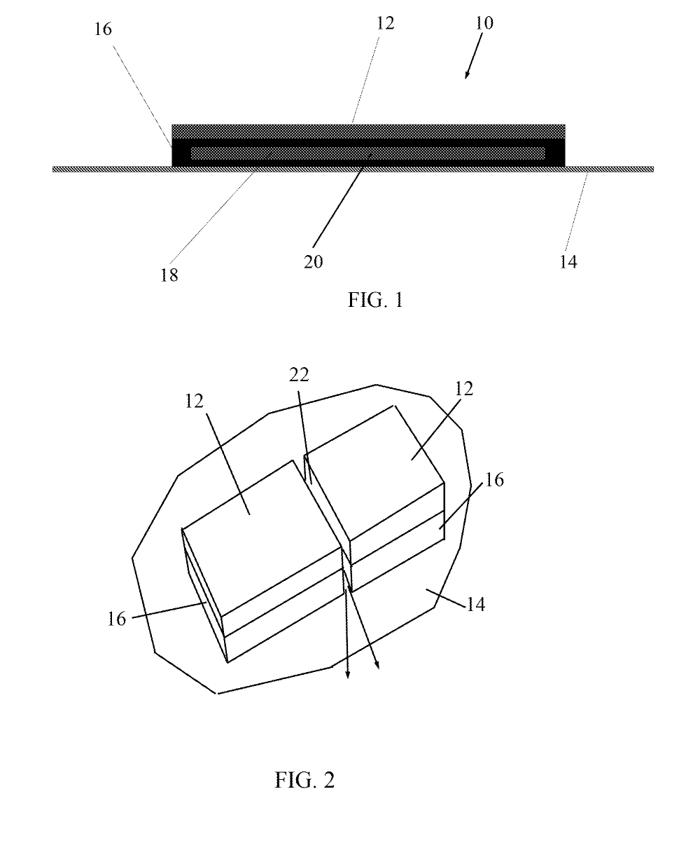

Reference is now made to FIG. 1, which illustrates a WIPV (Water Integrated Photovoltaic) module 10, constructed and operative in accordance with a non-limiting embodiment of the present invention.

WIPV module 10 includes a PV device, module or cell 12 (the terms being used interchangeably) bonded to a geomembrane 14 with an adhesive interface 16.

PV device 12 may be any commercially available PV device. Current photovoltaic technology basically includes two commercial module technologies:

1. Thick crystal products include solar cells made from crystalline silicon either as single or poly-crystalline wafers and deliver about 10-12 watts per ft² of PV array (under full sun).

2. Thin-film products typically incorporate very thin layers of photovoltaic active material placed on various low-cost substrates (or “superstrates”) such as glass, stainless steel, or plastic using vacuum-deposition manufacturing techniques, or alternatively, physical vapor deposition, chemical vapor deposition, electrochemical deposition, or a combination thereof. Presently, commercial thin-film materials deliver about 4-5 watts per ft² of PV array area (under full sun). Although the current technology provides less power for a given area than thick crystal products, thin-film technologies may achieve lower costs due to much lower requirements for active materials and energy in their production when compared to thick-crystal products.

An example of a suitable PV device is a polycrystalline thin-film cell. This cell has a heterojunction structure, in which the top layer is made of a different semiconductor material than the bottom semiconductor layer. The top layer, usually n-type, is a window that allows almost all the light through to the absorbing layer, usually p-type. A common material for the top or window layer is cadmium sulfide (CdS). Common materials for the absorbing layer include copper indium diselenide (CuInSe₂ or CIS) or cadmium telluride (CdTe), both of which have extremely high absorptivity.

Geomembrane 14 may be constructed, without limitation, of HYPALON, Dupont's trademark for chlorosulfonated polyethylene (CSPE) synthetic rubber, which has excellent resistance to chemicals, temperature extremes, and ultraviolet light. Geomembrane 14 may include the Pondgard® EPDM Liner or the blended Medium Density Polyethylene (MDPE) geomembrane, both commercially available from GSI, or any other suitable liner, membrane or other flexible substrate (all the terms being used interchangeably throughout). Another suitable geomembrane flexible floating cover material is manufactured by Comanco Company, 4301 Sterling Commerce Drive, Plant City, Fla. 33566 (www.comanco.com). Geomembrane 14 may be inflatable.

It is noted that geomembrane 14 alone does not have sufficient buoyancy to keep PV device 12 afloat above water.

Adhesive interface 16 may include, without limitation, a non-hardening and flexible adhesive tape, such as SIKA-68 brand ethylene propylene copolymer tape, commercially available from Sika Corporation, Lyndhurst, N.J., US. This adhesive tape has excellent characteristics as an environmentally stable seal that prevents moisture penetration to PV device 12, has good flexibility to conform/adhere to geomembrane 14 under temperature/humidity extremes, and also has excellent resistance to fungus/mildew/algae growth from developing on PV device 12.

In accordance with an embodiment of the present invention, adhesive interface 16 is formed with a buoyancy chamber 18 that is at least partially filled with a material 20. Material 20 may be sandwiched between upper and lower layers of the adhesive interface 16. As is well known in physics, if the weight of an object is less than the weight of the fluid the object would displace if it were fully submerged, then the object has an average density less than the fluid and has a buoyancy greater than its weight. This means the object will float at a level where it displaces the same weight of fluid as the weight of the object. In the present invention, the volume of chamber 18 and the properties of material 20 (particularly its density) are selected so PV device 12 floats upon a body of water (that is, does not completely sink below the upper surface of the body of water), preferably such that PV device 12 is completely above the upper surface of the body of water but alternatively may be selected so that PV device 12 is partially submerged. Material 20 may be, without limitation, air, foam (e.g., foamed polystyrene), foam rubber and others. Accordingly, adhesive interface 16, together with buoyancy chamber 18 and material 20, comprises a WIPV interface that may be customized for attaching a particular PV module 12 to geomembrane 14.

When partially submerged, the water functions as a magnifying glass to amplify the suns rays that impinge upon PV device 12.

Reference is now made to FIG. 2, which illustrates adjacent PV devices 12 mounted on geomembrane 14. Troughs or gaps 22 are created between adjacent PV devices 12, which are raised above geomembrane 14 by the adhesive interfaces 16. The troughs 22 help channel water, e.g., rain water or water from splashing or waves, in the direction indicated by the arrows back into the body of water. Thus, the presence of the adhesive interfaces 16 helps drain water away from the PV devices 12.

The adhesive interfaces 16 can be used to form a universal WIPV conversion system for standard PV products (as well as geomembranes from various suppliers) and turn them into WIPV ready products that are suitable/approved/certified for use in WIPV modules/systems. For example, the adhesive interfaces 16 can be used to convert a standard PV device into a WIPV product by adhering the adhesive interface 16 to one side of the PV device and then the PV device would become WIPV ready for bonding the other side of the adhesive interface 16 directly to an approved floating cover geomembrane.

It will be appreciated by persons skilled in the art that the present invention is not limited by what has been particularly shown and described hereinabove. Rather the scope of the present invention includes both combinations and subcombinations of the features described hereinabove as well as modifications and variations thereof which would occur to a person of skill in the art upon reading the foregoing description and which are not in the prior art.

What is claimed is:

1. A WIPV (Water Integrated Photovoltaic) module comprising:
a photovoltaic (PV) device bonded to a geomembrane with an adhesive interface, said adhesive interface being formed with a buoyancy chamber that is at least partially filled with a material, wherein a volume of said buoyancy chamber and properties of said material are selected such that said PV device does not completely sink below an upper surface of a body of water when said WIPV module is placed on the body of water.

2. The WIPV module according to claim 1, wherein the volume of said buoyancy chamber and the properties of said material are selected such that said PV device is completely above the top surface of the body of water when said WIPV module is placed on the body of water.

3. The WIPV module according to claim 1, wherein the volume of said buoyancy chamber and the properties of said material are selected such that said PV device is partially submerged below the top surface of the body of water when said WIPV module is placed on the body of water.

4. The WIPV module according to claim 1, wherein said material is air.

5. The WIPV module according to claim 1, wherein said material comprises foam.

6. The WIPV module according to claim 1, wherein said material comprises foamed polystyrene.

7. The WIPV module according to claim 1, wherein said material comprises foam rubber.

8. The WIPV module according to claim 1, further comprising a plurality of said PV devices mounted adjacent one another on said geomembrane and bonded to said geomembrane by a plurality of said adhesive interfaces, wherein troughs are created between the adjacent PV devices, which are raised above said geomembrane by said adhesive interfaces.

9. An interface for a WIPV module comprising:
an adhesive interface formed with a buoyancy chamber that is at least partially filled with a material, said adhesive interface being sufficiently adhesive to bond a PV device to a geomembrane, wherein a volume of said buoyancy chamber and properties of said material are selected such that the PV device does not completely sink below an upper surface of a body of water when said PV device together with the adhesive interface and geomembrane is placed on the body of water.

10. The interface according to claim 9, wherein said material is air.

11. The interface according to claim 9, wherein said material comprises foam.

12. The interface according to claim 9, wherein said material comprises foamed polystyrene.

13. The interface according to claim 9, wherein said material comprises foam rubber.

14. A method for constructing a WIPV module comprising:
bonding a photovoltaic (PV) device to a geomembrane with an adhesive interface, said adhesive interface being formed with a buoyancy chamber that is at least partially filled with a material; and
selecting a volume of said buoyancy chamber and properties of said material such that said PV device does not completely sink below an upper surface of a body of water when said WIPV module is placed on the body of water.

15. The method according to claim 14, comprising selecting the volume of said buoyancy chamber and the properties of said material such that said PV device is completely above the top surface of the body of water when said WIPV module is placed on the body of water.

16. The method according to claim 15, comprising selecting the volume of said buoyancy chamber and the properties of said material such that said PV device is partially submerged below the top surface of the body of water when said WIPV module is placed on the body of water.
